(19) United States
(12) Patent Application Publication
(10) Pub. No.: US 2013/0203202 A1
(43) Pub. Date: Aug. 8, 2013

(54) INTEGRATED VAPOR TRANSPORT DEPOSITION METHOD AND SYSTEM

(71) Applicant: FIRST SOLAR, INC., Perrysburg, OH (US)

(72) Inventors: Gang Xiong, Perrysburg, OH (US); John Barden, Ottawa Hills, OH (US); Feng Liao, Perrysburg, OH (US); Rick C. Powell, Ann Arbor, MI (US); Changming Jin, Sylvania, OH (US)

(73) Assignee: FIRST SOLAR, INC., Perrysburg, OH (US)

(21) Appl. No.: 13/754,535

(22) Filed: Jan. 30, 2013

Related U.S. Application Data
(60) Provisional application No. 61/592,985, filed on Jan. 31, 2012.

(51) Int. Cl. H01L 31/18

(52) U.S. Cl. CPC H01L 31/18
USPC 438/57; 118/719

(57) ABSTRACT

vapor transport deposition system and method that includes a vaporizer and distributor unit and at least one auxiliary process unit for integrating thin-film layer deposition with one or more pre- or post-deposition processes.

This application claims the benefit of priority of U.S. Provisional Patent Application No. 61/592,985, filed Jan. 31, 2012, entitled: “Integrated Vapor Transport Deposition Method and System,” the entirety of which is incorporated by reference herein.

### FIELD OF THE INVENTION

Disclosed embodiments relate to the field of photovoltaic device production, and more particularly to a material vapor transport deposition (VTD) method and system.

### BACKGROUND

Photovoltaic devices such as photovoltaic modules or cells can include semiconductor and other materials deposited over a substrate using various deposition systems and techniques. These various deposition systems may include a coater system, maintained under vacuum conditions. A typical coater system may comprise an entry load lock, a deposition chamber with a pre-deposition section, a thin-film deposition section, and a post-deposition section, and an exit load lock.

FIG. 1 illustrates one example of a typical coater system 70. Coater system 70 can include, for example, entry load lock 110, deposition chamber 105 with pre-deposition section 120, thin-film deposition section 130, post-deposition section 140, and exit load lock 150. Entry load lock 110 can be a chamber that includes doors 111, 112. During production, entry load lock 110 can cycle between two different pressure ranges, for example, atmospheric pressure and a process pressure that is to be maintained within deposition chamber 105. The deposition process can be started by transporting substrate 13 into entry load lock 110. When entry load lock 110 is at a first pressure, for example, atmospheric pressure, door 111 can open and substrate 13 can be transported into the chamber. After door 111 closes, the pressure in the chamber may be reduced or increased to coincide with the pressure in deposition chamber 105. In this particular example, the pressure is reduced to coincide with the pressure in the deposition chamber 105. After that, door 112 can open and substrate 13 can be released to deposition chamber 105 and transported through pre-deposition section 120, thin-film deposition section 130 and post-deposition section 140.

At pre-deposition section 120, substrate 13 can be heated to a process temperature and receive necessary pre-deposition thermal, chemical or thermal chemical treatment(s). At thin-film deposition section 130, vapor transport deposition system 20 can deposit one or more materials as thin-film layers on substrate 13. At post-deposition section 140, necessary post-deposition thermal, chemical or thermal chemical treatment(s) can be performed to the deposited thin-film layer and substrate 13.

Exit load lock 150 can be a chamber including two doors 151, 152. After processing within deposition chamber 105 is complete, door 151 can open and substrate 13 can be transported into exit load lock 150 and then door 151 can close. As in the case of entry load lock 110, exit load lock 150 can cycle between a first pressure and a second pressure. The first pressure may be the process pressure in the deposition chamber 105, and the second pressure may be atmospheric pressure or another pressure compatible with a downstream processing pressure. The operating mechanism of exit load lock 150 can be similar to the entry load lock 110. When the second process pressure has been achieved in exit load lock 150, door 152 can open and the substrate 13 can be transported from exit load lock 110 to any following manufacture process.

The vapor transport deposition system 20 is designed to vaporize or sublimate raw material powder into a gaseous form. In conventional powder vaporizers, raw material powder from a powder delivery unit is combined with a carrier gas and injected into a vaporizer formed as a permeable heated cylinder. The material is vaporized in the cylinder and the vaporized material flows through the permeable walls of the vaporizer into a vapor distributor. The distributor typically surrounds the vaporizer cylinder and directs collected vapors towards openings that face towards a substrate for thin-film material deposition on the substrate.

FIG. 2A illustrates one example of a conventional vapor transport deposition system 20 that can be part of coater system 70 described above. Vapor transport deposition system 20 can deliver and deposit a thin-film layer material onto a substrate 13, for example, a glass substrate 13 used in the manufacture of thin-film solar modules. To do so, inert carrier gas sources 25 and 27 respectively provide a carrier gas such as Helium (He) to powder feeders 21 and 23, which contain powder material. The gas transports the material through injector ports 17, 19 on opposite ends of a vaporizer and distributor assembly 10. The vaporizer and distributor assembly 10 vaporizes the material powder and distributes it for deposition onto substrate 13.

FIG. 2B is a cross-sectional view, taken along section line 2-2 of the conventional vapor transport deposition system 20 of FIG. 2A. In the figure, a distributor 50, vaporizer 12, and injector port 17 are shown. The vaporizer 12 is constructed as a heated tubular permeable member. It is formed of a resistive material which can be heated by AC power source 29 (see FIG. 2A) to vaporize powder transported by the carrier gas into vaporizer 12 through injection ports 17, 19. The distributor 50 is formed of a thermal-conductive material such as graphite or mullite, which is heated by radiant heat from vaporizer 12 and/or from another source. The distributor 50 surrounds vaporizer 12 to capture material vapor that flows through the walls of vaporizer 12. The material vapor is directed by distributor towards a slot or series of holes 14 which face a surface of substrate 13, which moves past the distributor 50. More detailed examples of VTD systems of the type illustrated can be found in U.S. Pat. Nos. 5,945,163, 5,945,165, 6,037,241, and 7,780,787, all assigned to First Solar, Inc.

Current coater systems that use the described vapor transport deposition system present some operational challenges. The cycling of entry and exit load locks may cause pressure fluctuations in the deposition chamber before deposition is initiated and undesired gas exchange between the load locks and the deposition chamber. These pressure fluctuations and gas exchanges can affect desired optimal ambient deposition conditions for thin-film layer production. Also, the layout of the coater system with separate zones for pre- and post-deposition chemical treatment or thermal chemical treatment may create inconsistent treatment conditions prior to and after deposition which can affect thin-film layer quality.

A vapor transport deposition system which mitigates against the noted problems and which can integrate thin-film layer deposition with other desired functions without expanding the coater system layout is desirable.

### DESCRIPTION OF DRAWINGS

FIG. 1 is a sectional view of a coater system;

FIG. 2A is a schematic of a conventional vapor transport deposition (VTD) system;

FIG. 2B is a cross-sectional view taken along the direction of line 2-2 in FIG. 2A to illustrate an example of a conventional vaporizer and distributor assembly;

FIG. 3 is a sectional view of a coater system;

FIG. 4 is a schematic of an embodiment of a vapor transport deposition (VTD) system;

FIG. 5 is a cross-sectional view taken along the direction of line 4-4 in FIG. 3 to illustrate an example of the FIG. 3 vaporizer and distributor assembly embodiment;

FIGS. 6A-6C are bottom plain views taken along the direction of line 5-5 of FIG. 4 to illustrate the varying size slit opening or openings of the apparatus;

FIGS. 7A-7B are cross-section views of the vaporizer and distributor assembly that illustrate alternative embodiments of the vapor transport deposition (VTD) system; and

FIG. 8 is a cross-sectional view of a vaporizer and distributor assembly with two auxiliary process units.

### DETAILED DESCRIPTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

According to an exemplary embodiment, a vapor transport deposition method and system are provided that can be configured to carry out vapor transport deposition and, in addition, provide one or more additional processing steps. The additional processing steps include: 1) gas flow curtain shielding to maintain optimal ambient deposition chamber conditions, 2) pre- and/or post-deposition thermal, chemical and/or thermal-chemical treatments of the substrate layer and/or semiconductor layer, and/or 3) dual- or tri-layer growth on the substrate.

This vapor transport deposition method and system may include a distributor mechanically coupled to a vaporizer unit and at least one auxiliary process unit for processing a substrate to provide one or more of the additional process steps described in the previous paragraph. The vaporizer unit and at least one auxiliary process unit may be permanently attached to the distributor, for example, by welding the units along the base of the distributor, or may be non-permanently attached to the distributor, for example, by using bolts or clips to attach the units to the distributor base. The vaporizer unit can vaporize or sublimate a raw material powder into a raw material vapor and the vapor may flow out of the vaporizer unit into a chamber in the distributor. The material vapor is then directed out of the distributor chamber for deposition on the substrate as a thin-film layer. In addition, at least one auxiliary process unit, constructed similarly to the vaporizer unit, but having an outlet directed toward a substrate, may be provided upstream or downstream of the vaporizer unit mechanically coupled to the distributor. The auxiliary process unit may provide a pre- or post-deposition process or other coating processes. Various gas or material sources, for example, an inert gas source, a chemical treatment process gas source, or a film forming material source may provide gas or material to the auxiliary process unit which may then be directed by an associated manifold housing of the auxiliary process unit towards the substrate through an opening in the manifold housing.

When the vapor transport deposition method and system includes a distributor mechanically coupled to a vaporizer unit and a single auxiliary process unit, the direction of substrate transport through the system may be varied based on the desired process. If a pre-deposition process is desired, the substrate may be transported through the system so that it passes under the auxiliary process unit prior to deposition of a thin-film layer by the vaporizer unit. If a post-deposition process is desired, the substrate may be transported through the system to that it passes under the auxiliary process unit after deposition of a thin-film layer by the vaporizer unit.

If a pre- and post-deposition process is desired, the vapor transport deposition method and system may include a distributor mechanically coupled to a vaporizer unit and at least two auxiliary process units, where the vaporizer unit is between the two auxiliary process units. The substrate may be transported through the system so that first, the substrate passes under the first auxiliary process unit for a pre-deposition process, then the substrate passes under the vaporizer unit for deposition of a thin-film layer, and finally, the substrate passes under the second auxiliary process unit for a post-deposition process.

The vapor transport deposition method and system may be part of a coater system as described above. However, since pre- and/or post-deposition processes are integrated into a single apparatus, the coater system may comprise an entry load lock, a deposition chamber with a single thin-film production zone, and an exit load lock. The deposition chamber may be more compact than deposition chambers discussed above since separate pre- and post-deposition apparatuses are not required.

During the deposition process, the vapor transport deposition system can accomplish the various desired functions listed above. For example, the system may help control ambient deposition chamber conditions by shielding the deposition section from the pressure fluctuations and undesired gas exchange caused by opening and closing entry and exit load locks in the coater system as described above. In one exemplary embodiment, the vapor transport deposition system can provide an gas curtain around the deposition section to reduce any negative effects that load lock cycling may have on ambient deposition conditions. The gas may be an inert gas, for example, nitrogen gas, that will not react with any material previously deposited on the incoming substrate or it may be any processes gas that can facilitate deposition of the next thin-film layer, for example, compressed dry air. The gas is injected into the auxiliary process unit, which then directs the gas in a constant stream towards the substrate. If the vapor transport deposition system includes a single auxiliary process unit and is arranged so that the substrate is transported under the auxiliary process unit prior to deposition of a thin-film layer by the vaporizer unit, then the constant flow of inert gas creates a gas curtain at the leading edge of the substrate. The gas curtain shields against pressure fluctuations or gas exchange caused by opening and closing the entry load locks in the coater system. If the vapor transport deposition system includes a single auxiliary process unit and is arranged so that the substrate passes under the manifold heater after deposition of the thin-film layer, then the constant flow of inert gas creates a gas curtain at the trailing edge of the substrate. The gas curtain shields against pressure fluctuations and undesired gas exchange caused by opening and closing the exit load locks in the coater system. If the vapor transport deposition system includes two auxiliary process units on opposite sides of the vaporizer unit, then the constant flow of inert gas from both units in opposite directions creates a gas curtain at the leading and trailing edge of the substrate as it moves through the system.

As another function, the system may provide pre- and/or post-deposition thermal heat treatments. In one embodiment, the auxiliary process unit may include a heater that is independent and separate from the vaporizer unit. The heat produced by the heater in the auxiliary process unit may be independently controlled to provide a thermal heat treatment of the substrate or a semiconductor layer deposited on the substrate. If the vapor transport deposition system includes a single auxiliary process unit with a heater and is arranged so that the substrate is transported under the auxiliary process unit prior to deposition of a thin-film layer by the vaporizer unit, then the auxiliary process unit may provide a pre-deposition thermal-heat treatment of the substrate. If the vapor transport deposition system includes a single auxiliary process unit with a heater and is arranged so that the substrate passes under the manifold heater after deposition of the thin-film layer, then the auxiliary process unit may provide a post-deposition thermal-heat treatment of the deposited semiconductor thin-film layer. If the vapor transport deposition system includes two auxiliary process units on opposite sides of the vaporizer unit, then the first auxiliary process unit can provide a pre-deposition thermal-heat treatment of the substrate and the second auxiliary process unit can provide a post-deposition thermal-heat treatment of the deposited semiconductor thin-film layer.

As another function, the system may provide pre- and/or post-deposition chemical treatments. For example, in a cadmium telluride-based photovoltaic module manufacturing process, injection of cadmium telluride through the vaporizer and distributor may cause variations in the deposition of the thin-film layer. In one exemplary embodiment, clean dry air (CDA), such as an oxygen and nitrogen mixture can be introduced into the auxiliary process unit and be directed at the substrate prior to or after cadmium telluride deposition to improve the quality of, for example, the interface between the cadmium telluride layer and the previously deposited semiconductor layer on the substrate. If the vapor transport deposition system includes a single auxiliary process unit and is arranged so that the substrate is transported under the auxiliary process unit prior to deposition of a thin-film layer by the vaporizer unit, then the auxiliary process unit may direct clean dry air at the substrate as a pre-deposition chemical treatment. If the vapor transport deposition system includes a single auxiliary process unit and is arranged so that the substrate passes under the manifold heater after deposition of the cadmium telluride thin-film layer, then the auxiliary process unit may direct clean dry air at the deposited thin-film layer as a post-deposition chemical treatment. If the vapor transport deposition system includes two auxiliary process units on opposite sides of the vaporizer unit, then the first auxiliary process unit can provide a pre-deposition chemical treatment of the substrate and the second auxiliary process unit can provide a post-deposition chemical treatment of the deposited cadmium telluride thin-film layer.

As another example function, the system may provide pre- and/or post-deposition thermal treatments and pre- and/or post-deposition chemical treatments simultaneously. For example, it may be desirable in some thin-film layer productions to simultaneously heat the substrate and treat the substrate with a chemical gas, for example CDA, prior to or following deposition of the semiconductor thin-film layer. If the vapor transport deposition system includes a single auxiliary process unit with a heater and is arranged so that the substrate is transported under the auxiliary process unit prior to deposition of a thin-film layer by the vaporizer unit, then the auxiliary process unit may heat the substrate and direct clean dry air at the substrate as a pre-deposition thermal-chemical treatment. If the vapor transport deposition system includes a single auxiliary process unit and is arranged so that the substrate passes under the manifold heater after deposition of the thin-film layer, then the auxiliary process unit may heat and direct clean dry air at the deposited thin-film layer as a post-deposition thermal-chemical treatment. If the vapor transport deposition system includes two auxiliary process units on opposite sides of the vaporizer unit, then the first auxiliary process unit can provide a pre-deposition thermal-chemical treatment of the substrate and the second auxiliary process unit can provide a post-deposition thermal-chemical treatment of the deposited thin-film layer.

As another function, the system may provide dual- or tri-layer growth on a substrate by directing a film forming material onto the substrate to be deposited as a secondary layer before and underneath and/or after and on top of the semiconductor thin-film layer. A secondary layer deposited on the substrate prior to deposition of the semiconductor thin-film layer may be called a seed layer and a secondary layer deposited on top of the semiconductor thin-film layer after deposition of the semiconductor thin-film layer may be called a surface cap layer. In one exemplary embodiment, a film forming material can be introduced into the auxiliary process unit and be directed at the substrate prior to or after thin-film layer deposition to deposit a seed layer on the surface of the substrate or a surface cap layer on the semiconductor thin-film layer. If the vapor transport deposition system includes a single auxiliary process unit and is arranged so that the substrate is transported under the auxiliary process unit prior to deposition of a thin-film layer by the vaporizer unit, then the auxiliary process unit may direct a film forming material at the substrate to form a seed-layer. If the vapor transport deposition system includes a single auxiliary process unit and is arranged so that the substrate passes under the manifold heater after deposition of the cadmium telluride thin-film layer, then the auxiliary process unit may direct a film forming material at the deposited thin-film layer to form a surface cap-layer. If the vapor transport deposition system includes two auxiliary process units on opposite sides of the vaporizer unit, then the first auxiliary process unit may direct a film forming material at the substrate to form a seed-layer and the second auxiliary process unit may direct a film forming material at the deposited thin-film layer to form a surface cap-layer, resulting in tri-layer growth.

A seed or cap layer may be formed using gas, liquid or solid material which is deposited using any acceptable deposition technique. For example, a film forming gas may be deposited using direct application of the gas to a surface of the substrate or the previously deposited layer. Alternatively, if the seed or cap layer is formed from a solid source, vapor transport deposition may be used to vaporize the solid material in the presence of a carrier gas and/or a process gas. The vaporized material may then be deposited to form the seed or cap layer. If, for example, the seed or cap layer is formed from a liquid source, the liquid material may be deposited using microdroplet transport or by vaporizing the liquid in the presence of a carrier gas that is passing through a heated bubbler, then depositing the vaporized material as the seed or cap layer.

It should also be noted and appreciated that, if the vapor transport deposition system includes two auxiliary process units on opposite sides of the vaporizer unit, then any of the aforementioned functions may be carried out by a first auxiliary process unit as a pre-deposition process while a different function may be carrier out by the second auxiliary process unit as a post-deposition process. For example, in one embodiment, it may be desirable to use one auxiliary process unit to provide a pre-deposition thermal treatment as described above and to use the second auxiliary process unit to provide a post-deposition chemical treatment as described above. In another embodiment, it may be desirable to use the first auxiliary process unit to direct a film forming material at the substrate to form a seed-layer and the second auxiliary process unit to provide a post-deposition chemical treatment of the deposited thin-film layer.

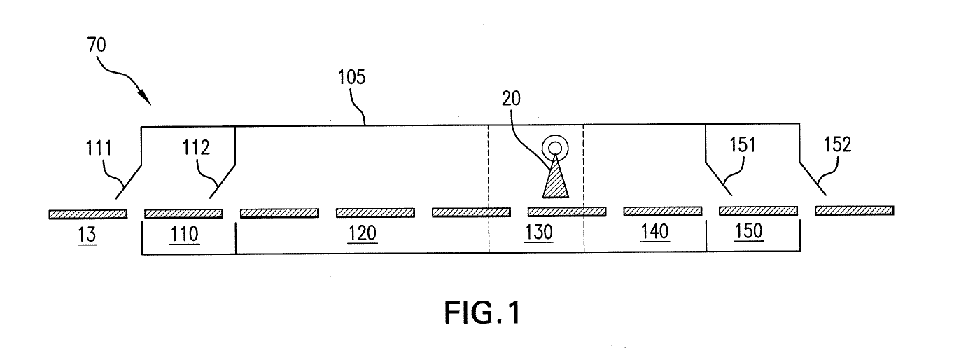

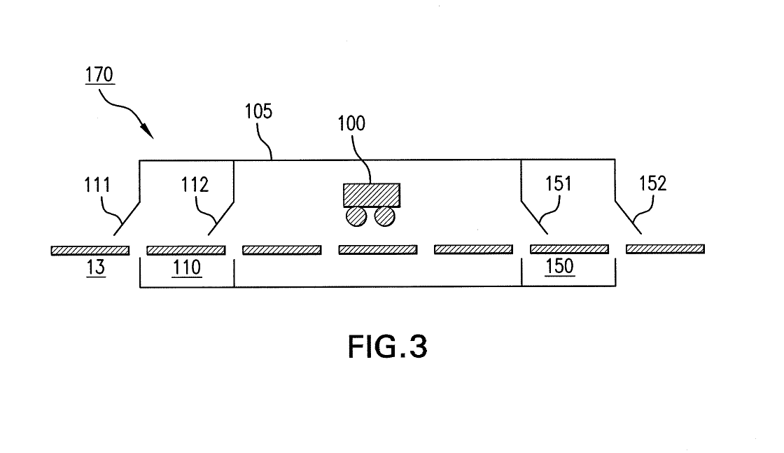

FIG. 3 illustrates a coater system 170 that includes an entry load lock 110, a deposition chamber 105 with a deposition system 100 and an exit load lock 150. Entry load lock 110 and exit load lock 150 may allow a substrate 13 to be transported in and out of deposition chamber 105 while adjusting pressure within coater system 170 from a first pressure, for example atmospheric pressure, to a second pressure, for example, a process pressure and back to the first pressure as described above with reference to FIG. 1. Deposition chamber 105 includes a deposition system 100, which may be any of the various embodiments described herein. Deposition system 100 can deposit one or more semiconductor materials as thin-film layers on substrate 13 and perform one or more additional processing steps as described above.

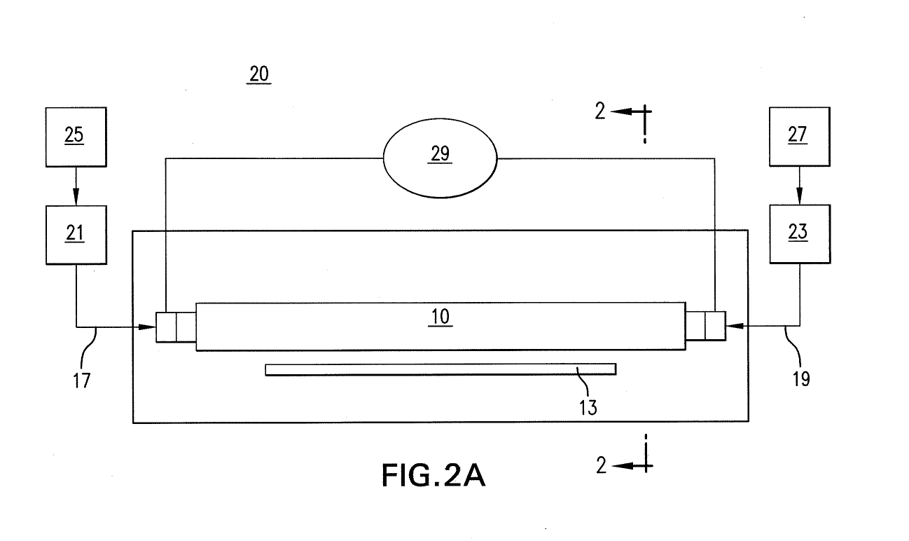

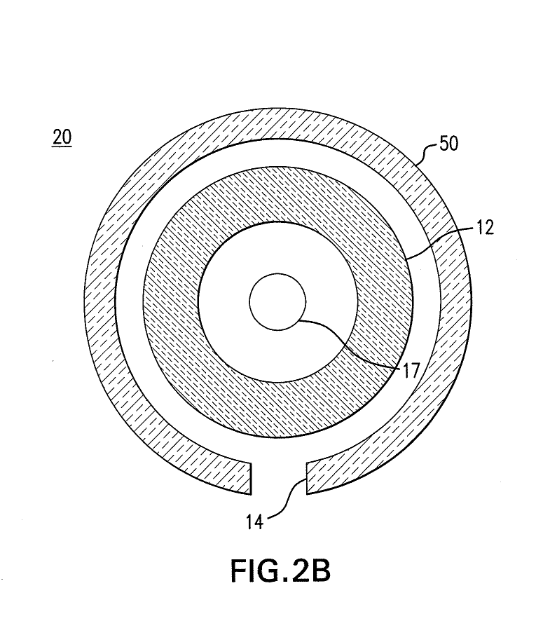

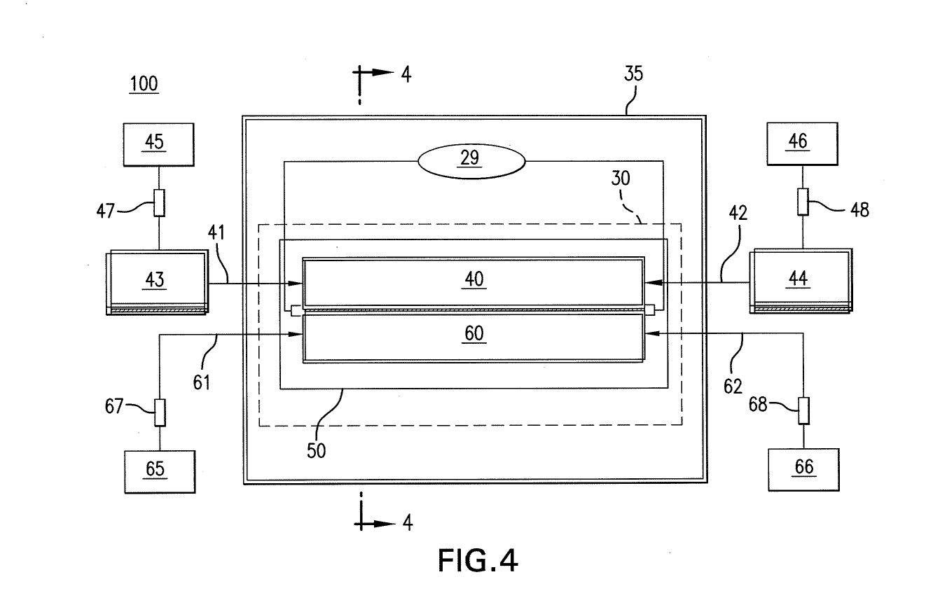

FIG. 4 illustrates an embodiment of a deposition system 100 that includes a vaporizer and a single auxiliary process unit attached to a distributor block for deposition of materials onto a substrate 13 (FIG. 2B), for example, a glass substrate used in the manufacture of thin-film solar modules. The deposition system includes a system assembly 30, which is housed within a vacuum vessel 35. System assembly 30 includes a vaporizer unit 40 mechanically coupled to a distributor unit 50, having respective vaporizer inlets 41, 42 at opposite ends for receiving vaporizable material powders from respective material feeders 43, 44. Inert carrier gas sources 45, 46, for example Helium gas (He) sources, respectively provide a carrier gas to material feeders 43, 44, through mass flow controllers 47, 48, to transport the raw material through respective vaporizer inlets 41, 42 into respective vaporizer unit 40. Mass flow controllers 47, 48 regulate the flow of carrier gas through respective material feeders 43, 44, which in turn control the flow rate of semiconductor material powder into respective vaporizer unit 40 and the flow rate of vaporizable material vapor into distributor unit 50.

Auxiliary process unit 60 is also mechanically coupled to distributor unit 50, having respective inlets 61, 62 at opposite ends for receiving material from respective material sources 65, 66. Material sources 65, 66, for example inert gas sources, process gas sources or layer forming material sources, provide gas or material to auxiliary process unit 60 through mass flow controllers 67, 68. Auxiliary process unit 60 directs the gas or material towards the substrate 13. Mass flow controllers 67, 68 regulate the flow of material to and ultimately out of the auxiliary process unit 60 towards the substrate 13.

Deposition system 100 can process substrate 13 for deposition of a semiconductor material, such as cadmium telluride and/or cadmium sulfide. In other embodiments, other substrates and deposition materials can also be utilized. For example, other materials can include indium sulfide (e.g., In₂S₃), indium selenide (e.g., In₂Se₃), zinc sulfide (e.g., ZnS), or zinc selenide (e.g., ZnSe). The deposition can take place on any suitable substrate, such as a glass substrate or a metal substrate such as foil. In addition, it may be possible to deposit materials with high vapor pressures such as zinc or lead at moderate temperatures.

Material feeders 43, 44 may be any type of material supplier that can be utilized for processing the raw material in a powder form and feeding the material powder into the system assembly 30, for example, vibratory powder feeders, fluidized bed feeders and rotary disk feeders that are commercially available. The vibration speed and/or amplitude used to process the raw material powder can also be used to control flow of raw material from material feeders 43, 44 through vaporizer unit 40 and to the distributor unit 50. The vibration speed and/or amplitude of the material feeders 43, 44 and the flow rate of mass flow controllers 47, 48 may be adjusted by a manual input or a digital/analog signal.

The inert carrier gases input from inert carrier gas sources 45, 46 can alternatively be another inert gas such as nitrogen, neon, argon or krypton, or combinations of these gases. It is also possible for the carrier gas to be mixed with and include some amount of a reactive gas such as oxygen that can advantageously affect growth properties of the material or hydrogen mixtures to encompass chemical treatments in a reducing atmosphere. A flow rate of about 0.1 to about 10 slpm of the carrier gas has been determined to be sufficient to facilitate flow of the powder out of material feeders 43, 44, through vaporizer unit 40 and through the distributor unit 50. Mass flow controllers 47, 48 may adjust flow rate between about 0.1 to about 10 slpm during the deposition process to control the thickness and/or composition of the deposited film. In alternative embodiments, for example, where material sources 65, 66 provide liquid or solid materials for deposition as a seed or cap layer on a substrate, mass flow controllers 67, 68 may control carrier gas flow into the material sources 65, 66 rather than from the material sources 65, 66 to the auxiliary process unit 60 as shown in FIG. 4.

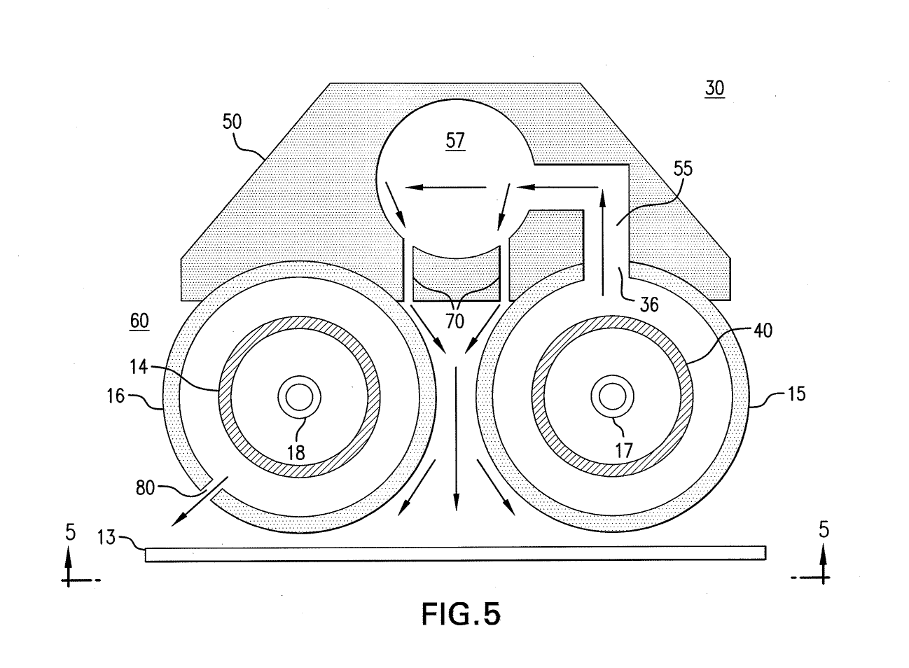

FIG. 5 illustrates a cross sectional view of the system assembly 30 in FIG. 4, taken along section line 4-4. As shown in FIG. 4, vaporizer unit 40 is enclosed within and mechanically coupled to the distributor unit 50. Vaporizer unit 40 is comprised of a permeable tubular wall, which is formed of a resistive material heated by AC power source 29 (FIG. 4) and which vaporizes material powder carried by an inert gas, e.g. Helium gas (He), alone or mixed with a reactive gas, from inlets 41, 42 through injection port 17. Distributor unit 50 comprises a vapor housing 15, formed of a thermal-conductive material, for example, graphite, or an insulator, for example, mullite, which is heated by radiant heat from vaporizer unit 40 and/or from an external source. The vapor housing 15 encloses vaporizer unit 40 to capture material vapor that flows through the permeable tubular walls of vaporizer unit 40. Vaporized material is directed within the vapor housing 15, out of opening 36 and through respective channel 55 to distributor chamber 57 in distributor unit 50. Vaporized material collected in distributor chamber 57 from respective vaporizer unit 40 is then directed towards openings 70, which may each be configured as a long slit opening or a plurality of spaced openings along the distributor unit 50, which direct the respective material vapor out of the distributor unit 50 to be deposited onto a substrate 13.

As shown in FIG. 5, auxiliary process unit 60 is mechanically coupled to distributor unit 50 and in one exemplary embodiment is comprised of a permeable tubular heater 14, which is formed of a resistive material heated by AC power source 29 (FIG. 4) and which provides ambient heat to the surrounding area and heats material received from inlets 61, 62 through injection port 18. A manifold housing 16 is formed of a thermal-conductive material, for example, graphite, or an insulator, for example, mullite, which is heated by radiant heat from heater 14 and/or from an external source. The manifold housing 16 encloses heater 14 to capture gas that flows through the permeable tubular wall of heater 14. Gas is directed towards opening 80, which may be configured as a long slit opening or a series of spaced openings arranged along manifold housing 16 that directs the gas out of the auxiliary process unit 60.

The vaporizer unit 40 and the heater 14 are made of any permeable material that is preferably electrically conductive, such as silicon carbide, and heated by AC power 29 to provide for heating, vaporization and/or sublimation of material or gas. Furthermore, the vapor housing 15 and the manifold housing 16 are generally a tubular shape that encloses the vaporizer unit 40 and the heater 14, as illustrated in FIG. 5.

Vaporizer unit 40 and heater 14 provide radiant heat to the surface of distributor unit 50 sufficient to maintain a temperature of about 900 to about 1200° C. in the distributor chamber 57. Vapor pressure within distributor chamber 57 is between about 1 to about 10 Torr. In some embodiments, the deposition temperature can be in the range between 200° to 700° C. For example, the pre- or post-deposition thermal treatment temperature range can be 100° to 1200° for Zinc Sulfide. In other embodiments, the temperature range can be 100° to 1500°.

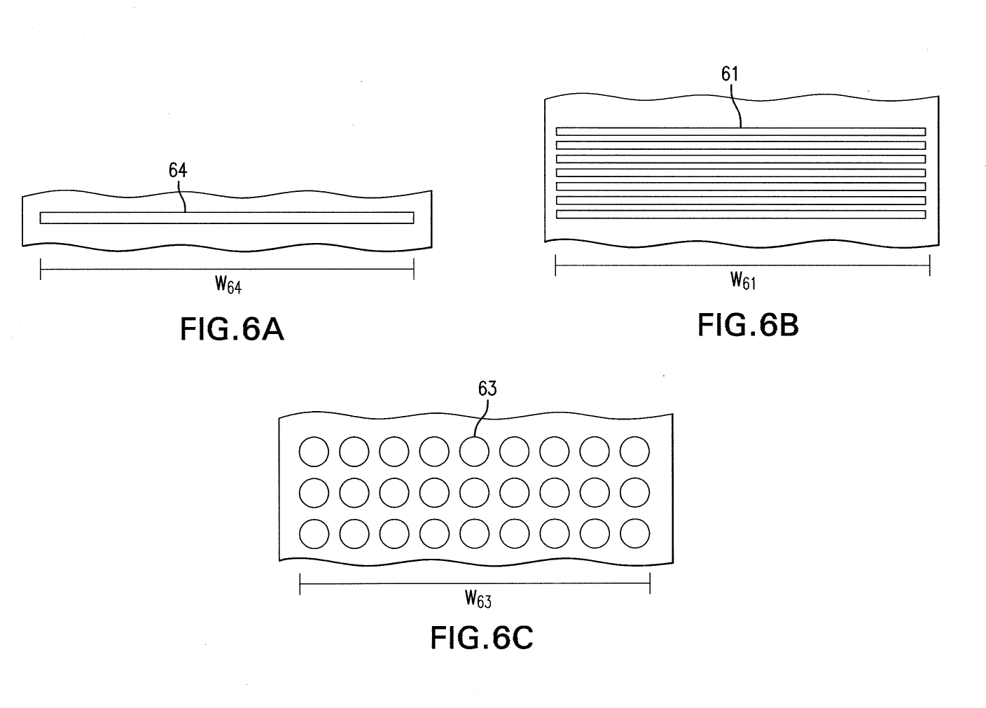

The openings 70 for directing the material vapor out of the distributor chamber 57 may be a slit 64, as shown in FIG. 6A, a plurality of slits 61, as shown in FIG. 6B, or a plurality of holes 63, as shown in FIG. 6C. The slits 64, 61 may extend along the base of the distributor unit 50 between and/or parallel to vapor housing 15 and the auxiliary process unit 60. As shown in FIG. 6B, the plurality of slits 61 may each have the same width W₆₁. In other embodiments, the plurality slits 61 may have different widths W₆₁ from each other. The plurality of slits 61 may be parallel to each other. The plurality of holes 63 of FIGS. 6C may be circular, oblong, square, rectangular, or other regular or irregular shapes. The plurality of holes 63 may be evenly spaced along the base of the distributor unit 50 between vapor housing 15 and the auxiliary process unit 60. The plurality of holes 63 may be arranged in a plurality of rows and columns, as shown in FIG. 6C. In another embodiment, the plurality of holes 63 may be arranged in a single row. In various embodiments, the width of the single slit W₆₄, the width of the plurality of slits W₆₁, and the width of the plurality of holes W₆₃, may be sized to shorter than the width of the substrate 13 to deposit material on less than the entire substrate 13.

The opening 80 for directing the gas out of the auxiliary process unit 60 may be a slit 64, as shown in FIG. 6A, a plurality of slits 61, as shown in FIG. 6B, or a plurality of holes 63, as shown in FIG. 6C. The slits 64, 61 may extend along the length of the manifold housing 16. As shown in FIG. 6B, the plurality of slits 61 may each have the same width W₆₁. In other embodiments, the plurality slits 61 may have different widths W₆₁ from each other. The plurality of slits 61 may be parallel to each other. The holes 63 of FIG. 6C may be circular, oblong, square, rectangular, or other regular or irregular shapes. The plurality of holes 63 may be evenly spaced along the length of the manifold housing 16. The plurality of holes 63 may be arranged in a plurality of rows and columns, as shown in FIG. 6C. In another embodiment, the plurality of holes 63 may be arranged in a single row. In various embodiments, the width of the single slit W₆₄, the width of the plurality of slits W₆₁, and the width of the plurality of slits W₆₃, may be sized to shorter than the width of the substrate 13 to direct gas on less than the entire substrate 13.

If deposition ambient control is desired to overcome the pressure fluctuations and undesired gas exchange in vacuum vessel 35, an inert gas, for example, helium gas, flows into material sources 65, 66. Mass flow controllers 67, 68 control the flow of the inert gas from the material sources 65, 66 through inlets 61, 62 into permeable tubular heater 14. The inert gas flows through the permeable tubular heater 14 and is captured by manifold housing 16, which directs the gas out of openings 80 to form an inert gas curtain at either the leading edge of substrate 13 as it moves towards the system assembly 30 or the trailing edge of the substrate as it moves away from the system assembly 30.

If the desired thin-film-production requires a pre- or post-deposition thermal heat treatment without gas flow. Gas flow from the material sources 65, 66 is stopped using mass flow controller 67, 68. Permeable tubular heater 14 is heated to the desired temperature to provide a thermal heat treatment to the substrate as it passes under the auxiliary process unit 60. If the desired thin-film-production requires a pre- or post-deposition chemical heat treatment, a process gas, for example, CDA, is loaded into material sources 65, 66. Mass flow controllers 67, 68 control the flow of the process gas from the material sources 65, 66 through inlets 61, 62 into permeable tubular heater 14. The process gas flows through the permeable tubular heater 14 and is captured by manifold housing 16, which directs the gas out of openings 80 towards the substrate. If the desired thin-film-production requires a pre- or post-deposition thermal chemical treatment, then a process gas is supplied through the auxiliary process unit 60 and directed towards the substrate while the permeable tubular heater 14 provides a thermal heat treatment.

If the desired thin-film-production requires the growth of an additional gas formed layer, as a seed layer or a cap layer to the semiconductor thin-film layer, a film forming gas, for example to form a seed layer or to form a cap layer, is loaded into material sources 65, 66. Mass flow controllers 67, 68 control the flow of the film forming gas from the material sources 65, 66 through inlets 61, 62 into permeable tubular heater 14. The process gas flows through the permeable tubular heater 14 and is captured by manifold housing 16, which directs the gas out of openings 80 towards the substrate prior to or following semiconductor thin-film layer deposition.

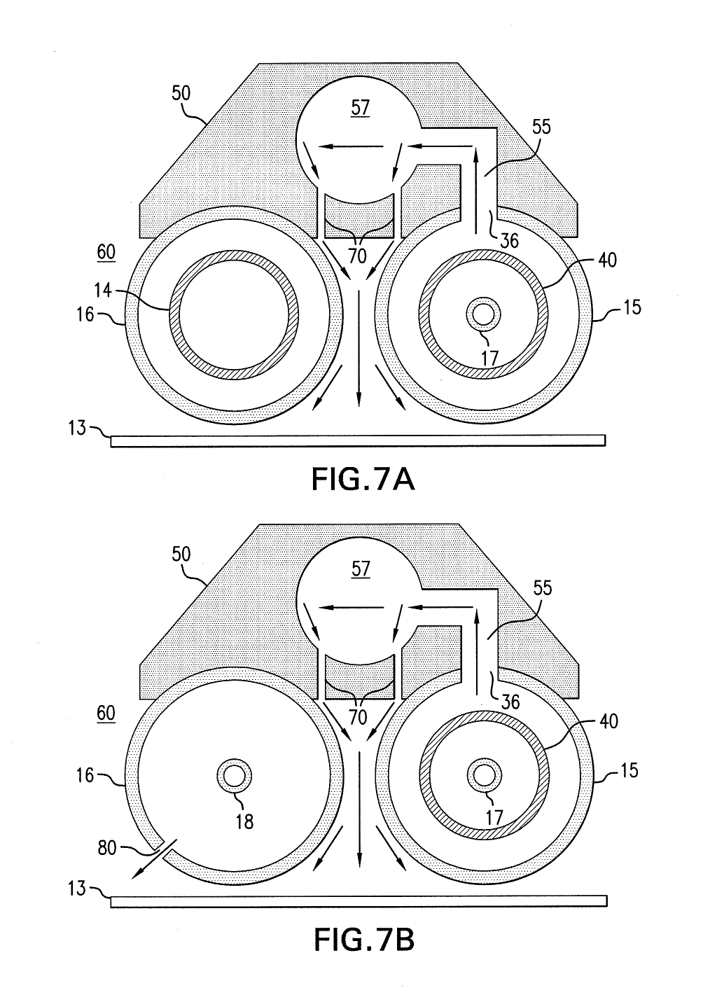

In alternative embodiments, components of auxiliary process unit 60 may be removed depending on the desired pre- or post-deposition process. For example, if the desired pre- or post-deposition process is only a thermal treatment, auxiliary process unit 60 may include only permeable tubular heater 14 mechanically coupled to distributor unit 50, as shown in FIG. 7A. A housing 16 is formed of a thermal-conductive material, for example, graphite, or an insulator, for example, mullite, which is heated by radiant heat from heater 14 and/or from an external source. The housing 16 encloses heater 14 to moderate the amount of radiant heat reaching the substrate 13. If the desired pre-or post-deposition process is only a chemical treatment, auxiliary process unit 60 may include only a tubular manifold housing 16 with injection port 18, as shown in FIG. 7B. The manifold housing 16 captures the treatment material injected through injection port 18 and directs the material out of the auxiliary process unit 60 through openings 80 facing towards the substrate for treatment of the substrate or the semiconductor thin-film layer.

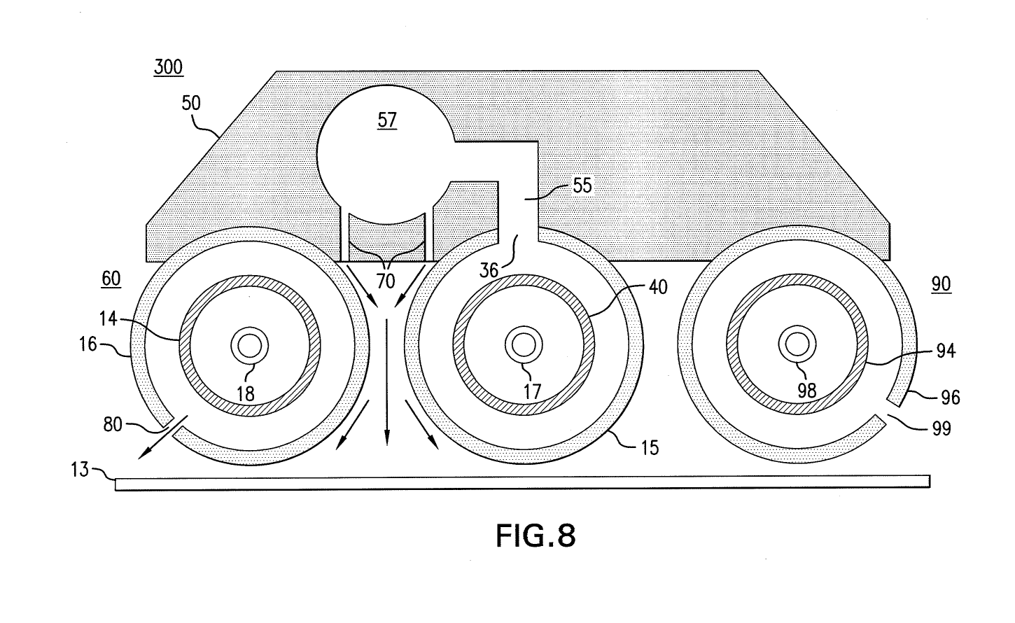

FIG. 8 illustrates a cross sectional view of an alternative embodiment of the vapor transport system which includes a vaporizer unit and two auxiliary process units. As shown in FIG. 8, system assembly 300 includes vaporizer unit 40, a first auxiliary process unit 60 and a second auxiliary process unit 90. Vaporizer unit 40 and first auxiliary process unit 60 operate and function as describe in reference to FIG. 5. Similar to first auxiliary process unit 60, second auxiliary process unit 90 is mechanically coupled to distributor unit 50 and in one exemplary embodiment is comprised of a permeable tubular heater 94, which is formed of a resistive material heated by AC power source 29 (FIG. 4) and which provides ambient heat to the surrounding area and heats material received through injection port 98. As with the vaporizer unit and the first auxiliary process unit, the second auxiliary process unit may be permanently attached to the distributor, for example, by welding the unit along the base of the distributor, or may be non-permanently attached to the distributor, for example, by using bolts or clips to attach the unit to the distributor base. A manifold housing 96 is formed of a thermal-conductive material, for example, graphite, or an insulator, for example, mullite, which is heated by radiant heat from heater 94 and/or from an external source. The manifold housing 96 encloses heater 94 to capture gas that flows through the permeable tubular wall of heater 94. Gas is directed towards opening 99, which may be configured as described with reference to opening 80 of the first auxiliary process unit.

If the desired thin-film production requires pre- and post deposition processes as described above, first auxiliary process unit 60 may provide pre-deposition processes for the substrate prior to deposition of the thin-film layer by vaporizer unit 40 and second auxiliary process unit 90 may provide post-deposition processes for the deposited semiconductor thin-film layer after deposition. As describe above, auxiliary process unit 60 and auxiliary process unit 90 may provide any combination of a shielding gas flow curtain, pre- and post-deposition thermal, chemical and/or thermal-chemical treatments of the substrate layer and/or semiconductor layer, and/or tri-layer growth on the substrate.

While embodiments have been described in detail, it should be readily understood that the invention is not limited to the disclosed embodiments. Rather the embodiments can be modified to incorporate any number of variations, alterations, substitutions, or equivalent arrangements not heretofore described without departing from the spirit and scope of the invention.

What is claimed as new and desired to be protected by Letters Patent of the United States is:

1. An apparatus comprising:
a deposition chamber comprising:
a vaporizer unit for vaporizing powder material;
a vapor distribution unit for collecting and outputting vapor from the vaporizer unit and depositing a first material layer on a substrate; and
a first auxiliary process unit mechanically coupled to said vapor distribution unit for providing a process which is independent of processes performed by said vapor distribution unit.

2. The apparatus of claim 1, wherein the first auxiliary process unit provides a pre-deposition process or a post-deposition process.

3. The apparatus of claim 1, wherein the vapor distribution unit further comprises:
a vapor housing for capturing vapor from the vaporizer unit;
a chamber for collecting the vapor captured by the vapor housing; and
a chamber outlet for deposition of the vapor collected in the chamber.

4. The apparatus of claim 3, wherein the first auxiliary process unit further comprises:
a permeable heater tube having at least one material inlet port for receiving a process material.

5. The apparatus of claim 4, wherein the first auxiliary process unit further comprises:
a manifold housing surrounding the permeable heater tube for capturing the vapor that flows out of the permeable heater tube, wherein the manifold housing has at least one opening for directing the vapor from the interior of the manifold housing toward a substrate.

6. The apparatus of claim 5, wherein the vaporizer unit further comprises:
a first permeable member having first and second material inlet ports for receiving first and second powder materials.

7. The apparatus of claim 6, further comprising first and second vibration powder feeders for respectively feeding the first and second powder materials into the respective first and second inlet ports of the vaporizer unit.

8. The apparatus of claim 7, further comprising first and second gas sources for directing gas through respective first and second mass flow controllers into the respective first and second vibration powder feeders.

9. The apparatus of claim 8, further comprising at least one material source for directing material through at least one mass flow controller into the at least one of the material inlet ports of the first auxiliary process unit.

10. The apparatus of claim 1, wherein the first auxiliary process unit creates a virtual curtain of inert gas around the substrate.

11. The apparatus of claim 1, wherein the first auxiliary process unit provides a chemical treatment process.

12. The apparatus of claim 1, wherein the first auxiliary process unit provides a vapor deposition on the substrate.

13. The apparatus of claim 1, wherein the first auxiliary process unit provides a vapor to form a material layer on the substrate.

14. The apparatus of claim 13, wherein the material layer is deposited before deposition by the vapor distribution unit.

15. The apparatus of claim 13, wherein the material layer is deposited after deposition by the vapor distribution unit.

16. The apparatus of claim 1, further comprising a second auxiliary process unit.

17. The apparatus of claim 16, wherein the first auxiliary process unit provides a pre-deposition process and the second auxiliary process unit provides a post-deposition process.

18. A method for manufacturing a photovoltaic device comprising:
depositing a thin film layer on a substrate using an integrated deposition apparatus; and
performing a first pre- or post-deposition process on the substrate using said integrated deposition apparatus.

19. The method of claim 18, wherein the step of depositing a thin film layer on a substrate further comprises:
vaporizing a material powder into a vapor;
collecting the vapor in a vapor distribution unit of said apparatus; and
outputting the vapor from the vapor distribution unit to be deposited onto the substrate.

20. The method of claim 19, wherein the step of performing a pre- or post-deposition process on the substrate further comprises performing a thermal heat treatment.

21. The method of claim 19, wherein the step of performing a pre- or post-deposition process on the substrate further comprises:
inputting a process material into a first auxiliary process unit of said apparatus; and
outputting the process material from the first auxiliary process unit towards a substrate.

22. The method of claim 21, wherein the step of collecting the vapor in the vapor distribution unit further comprises:
capturing the vapor from the vaporizer unit in a vapor housing; and
passing the vapor from the vapor housing to a chamber in the vapor distribution unit.

23. The method of claim 22, wherein the step of inputting a process material into a first auxiliary process unit further comprises:
inputting a process material from a material source into at least one inlet in the first auxiliary process unit;
capturing the process material in a manifold housing of the first auxiliary process unit; and
directing the process material towards an opening in the manifold housing.

24. The method of claim 18, wherein the step of performing a pre- or post-deposition process on the substrate comprising performing a pre-deposition process.

25. The method of claim 24, wherein the step of performing a pre-deposition process comprises forming an upstream inert gas curtain adjacent to the substrate to achieve local ambient control.

26. The method of claim 24, wherein the step of performing a pre-deposition process comprises performing a pre-deposition chemical treatment with a process gas.

27. The method of claim 24, wherein the step of performing a pre-deposition process comprises performing a pre-deposition thermal-chemical treatment with a process gas and radiant heat.

28. The method of claim 24, wherein the step of performing a pre-deposition process comprises performing a pre-deposition thermal treatment of the substrate with radiant heat and without gas flow.

29. The method of claim 24, wherein the step of performing a pre-deposition process comprises providing a vapor to form a material layer on the substrate.

30. The method of claim 18, wherein the step of performing a pre- or post-deposition process on the substrate comprising performing a post-deposition process.

31. The method of claim 30, wherein the step of performing a post-deposition process comprises forming an downstream inert gas curtain adjacent to the substrate to achieve local ambient control.

32. The method of claim 30, wherein the step of performing a post-deposition process comprises performing a post-deposition chemical treatment with a process gas.

33. The method of claim 30, wherein the step of performing a post-deposition process comprises performing a post-deposition thermal-chemical treatment with a process gas and radiant heat.

34. The method of claim 30, wherein the step of performing a post-deposition process comprises performing a post-deposition thermal treatment of the substrate with radiant heat and without gas flow.

35. The method of claim 30, wherein the step of performing a post-deposition process comprises providing a vapor to faun a material layer on a deposited layer on the substrate.

36. The method of claim 23, further comprising:
performing a second pre- or post-deposition process on the substrate using said integrated deposition apparatus.

37. The method of claim 36, further comprising:
inputting a process material into a second auxiliary process unit of said apparatus; and
outputting the process material from the second auxiliary process unit towards the substrate.

38. The method of claim 37, further comprising:
directing the substrate under the first auxiliary process unit for a pre-deposition process;
after directing the substrate under the first auxiliary process unit, directing the substrate under the vapor distribution unit; and
after directing the substrate under the vapor distribution unit, directing the substrate under the second auxiliary process unit for a post deposition process.
